(19) United States
(12) Patent Application Publication
(10) Pub. No.: US 2026/0075801 A1
(43) Pub. Date: Mar. 12, 2026

(54) MEMORY DEVICE AND METHOD FOR MANUFACTURING THE SAME

(71) Applicant: Winbond Electronics Corp., Taichung City (TW)

(72) Inventors: Chien-Liang WU, Tainan City (TW); Yi-Hao CHIEN, Taichung City (TW)

(21) Appl. No.: 19/319,366

(22) Filed: Sep. 4, 2025

(30) Foreign Application Priority Data
Sep. 6, 2024 (TW) 113133878

(51) Int. Cl. H10B 12/00; H01L 21/265

(52) U.S. Cl. CPC H10B 12/315; H10B 12/0335; H10B 12/34; H10B 12/482; H10B 12/485; H10B 12/50; H10P 30/209; H10B 12/09

(57) ABSTRACT

A method for manufacturing a memory device includes providing a substrate, an array region of the substrate includes a central region and an edge region surrounding the central region, and the substrate includes a first active region and a second active region separated by an isolation structure. The method includes sequentially forming a bit line contact and a bit line structure over the first active region, conformally forming a dielectric liner on the substrate to cover the bit line contact and the bit line structure, and performing an etching process on the substrate to form a trench and expose the second active region. The method further includes performing an ion implantation process on the trench in the edge region to form an insulating layer at a bottom of the trench and covering the second active region, and forming a capacitor contact structure over the second active region.

### CROSS REFERENCE TO RELATED APPLICATIONS

This application claims priority of Taiwan patent application No. 113133878, filed Sep. 6, 2024, the entirety of which is incorporated by reference herein.

### TECHNICAL FIELD

The present disclosure relates to semiconductor technology, and, in particular, it relates to a method for manufacturing a memory device.

### BACKGROUND

In current memory device fabrication processes, the continuous downscaling of device dimensions has resulted in a corresponding reduction in process margins. For instance, after the formation of embedded word line and bit line structures, subsequently formed capacitor contact structures may, due to process variations, cause a short circuit between the active region located in a dummy region and a subsequently formed conductive layer due to contact with the capacitor. Such short circuits may lead to leakage current and degrade the reliability of the memory device. Accordingly, there remains a need in the industry to improve memory device manufacturing methods to ensure quality and maintain device yield.

### BRIEF SUMMARY

An embodiment of the present disclosure provides a method for manufacturing a memory device, including providing a substrate. The array region of the substrate includes a central region and a boundary region. The boundary region surrounds the central region. The substrate includes a first active region and a second active region, which are separated by an isolation structure. The method further includes sequentially forming a bit line contact and a bit line structure over the first active region of the substrate. The method further includes conformally forming a dielectric liner on the substrate to cover sidewalls of the bit line contact and the bit line structure and the top surface of the bit line structure. The method further includes performing an etching process on the substrate to form a trench that exposes the second active region. The method further includes performing an ion implantation process in the trench, which is located in the boundary region of the substrate, to form an insulating layer at the bottom of the trench and to cover the second active region. The method further includes forming a capacitor contact structure over the second active region.

An embodiment of the present disclosure provides a memory device. The memory device includes a substrate. The array region of the substrate includes a central region and a boundary region. The boundary region surrounds the central region. The substrate includes a first active region and a second active region, which are separated by an isolation structure. The memory device further includes a bit line structure disposed over the first active region of the substrate. The memory device further includes a trench disposed over the second active region of the substrate. The memory device further includes an insulating layer located at the bottom of the trench. The insulating layer covers the second active region and a capacitor contact structure that is disposed over the second active region and filled into the trench.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a top view of the substrate of the memory device according to the embodiments of the present disclosure.

FIGS. 2, 3, 4, and 5 illustrate cross-sectional views of the intermediate stages in the manufacturing of the memory device according to the embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first feature and the second feature are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

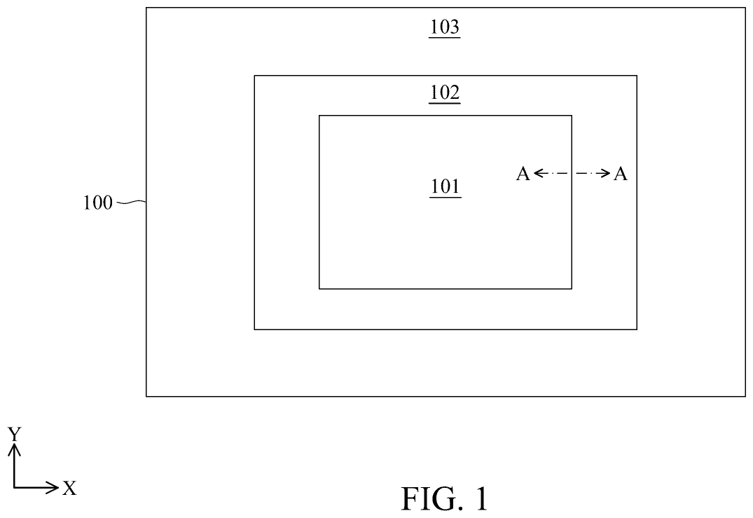

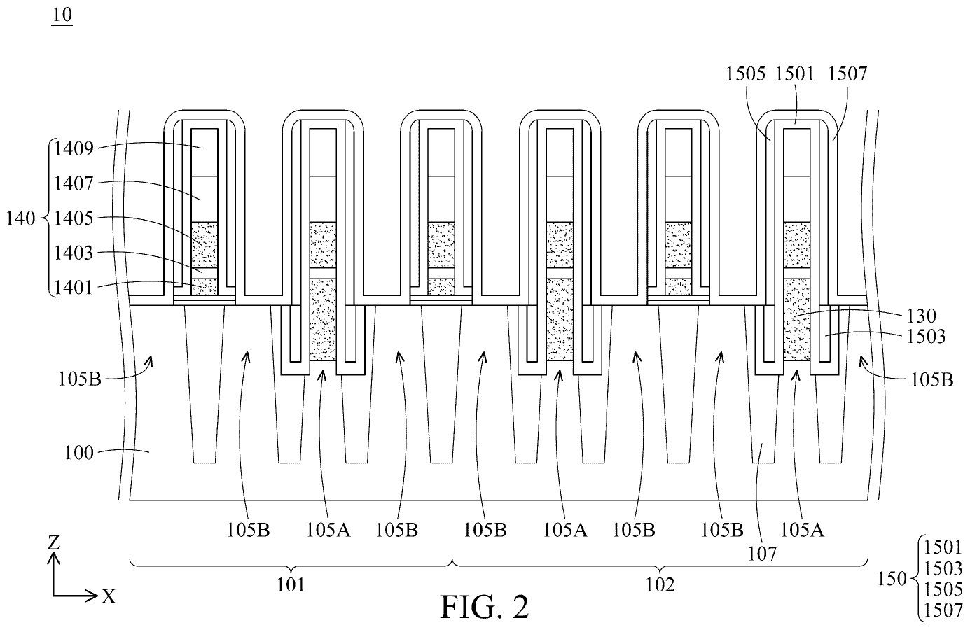

FIG. 1 illustrates a top view of the substrate 100 of the memory device 10 according to the embodiments of the present disclosure. FIGS. 2, 3, 4, and 5 illustrate cross-sectional views of the intermediate stages in the manufacturing of the memory device 10 according to the embodiments of the present disclosure. FIGS. 2, 3, 4, and 5 correspond to a cross-sectional view taken along line A-A of FIG. 1.

Referring first to FIG. 1, a substrate 100 is provided. The substrate 100 includes an array region and a peripheral region 103 surrounding the array region. The array region further includes a central region 101 and a boundary region 102 surrounding the central region 101. In general, the boundary region 102 serves as a dummy region. In an embodiment, the substrate 100 may be an elemental semiconductor substrate, such as a silicon substrate or a germanium substrate; a compound semiconductor substrate, such as silicon carbide (SiC), gallium arsenide (GaAs), indium arsenide (InAs), or indium phosphide (InP) substrate; or an alloy semiconductor substrate, such as SiGe, SiGeC, GaAsP, or GaInP. In other embodiments, the substrate 100 may be a semiconductor-on-insulator (SOI) substrate, which may include a base substrate, a buried oxide layer disposed on the base substrate, and a semiconductor layer disposed on the buried oxide layer.

The substrate 100 includes a first active region 105A and a second active region 105B, and the first active region 105A and the second active region 105B are separated from each other by an isolation structure 107. In an embodiment, the substrate 100 includes an embedded word line structure (not shown), the embedded word line structure serves as a gate of the memory device 10 and may include a gate liner and a gate electrode. The gate liner may be formed of tungsten nitride, titanium nitride, or tantalum nitride. The gate electrode may be formed of a conductive material, such as doped polysilicon, metal, or metal nitride. In an embodiment, the substrate 100 may further include a protective layer (not shown) formed on the embedded word line structure, which functions as a dielectric layer for controlling the channel of the memory device 10.

Referring to FIG. 2, a bit line structure 140 is formed on the substrate 100, and a bit line contact 130 extending to the substrate 100 may also be formed. The bit line contact 130 is in direct contact with a corresponding active region (e.g., the first active region 105A located beneath the bit line contact 130). In an embodiment, the bit line structure 140 may include, from bottom to top, a conductive layer 1401, a conductive layer 1403, a conductive layer 1405, a dielectric layer 1407, and a cap layer 1409. The dielectric layer 1407 and the cap layer 1409 serve to protect the underlying layers (such as conductive layers 1401, 1403, or 1405) from damage during subsequent processing. In an embodiment, during the formation of the above-mentioned stacked structure, a portion of the bit line contact 130 and the adjacent regions of the substrate 100 on opposite sides of the bit line contact 130 are partially removed to form recesses on opposite sides of the bit line contact 130. These recesses expose portions of the active region (e.g., the first active region 105A) and portions of the isolation structure 107. Subsequently, spacer structures 150 are formed on sidewalls of the bit line structure 140 and in the recesses. In some embodiments, the spacer structures 150 may also be referred to as a dielectric liner for electrically isolating subsequent structures. The spacer structures 150 include a combination of different dielectric materials. In an embodiment, a first spacer material layer 1501 is conformally formed along the sidewalls of the bit line structure 140 and the recesses, followed by forming a second spacer material layer 1503 to fill the remaining recesses. Then, additional spacer material layers 1505 and 1507 are sequentially formed over the sidewalls of the bit line structure 140, thereby isolating the bit line contact 130 and the bit line structure 140 from a subsequently formed capacitor contact structure 200.

In an embodiment, the conductive material (the bit line contact 130) may include doped polysilicon, metal, or metal nitride.

In an embodiment, the conductive layers 1401, 1403, and 1405 may include doped polysilicon, metal, or metal nitride, such as tungsten (W), titanium (Ti), and titanium nitride (TiN). In an embodiment, the upper conductive layer 1405 has a lower resistivity than the conductive layer 1401. In an embodiment, the dielectric layer 1407 and the cap layer 1409 may include silicon oxide, silicon nitride, or a combination thereof.

In an embodiment, the material of the spacer structure 150 (e.g., the spacer material layers 1501, 1503, 1505, and 1507) may include a nitride material, an oxide material, or a combination thereof. In an embodiment, the spacer structure 150 may be formed by a deposition process and an etching process. The deposition process may include chemical vapor deposition (CVD) process, atomic layer deposition (ALD) process, or a combination thereof. The etching process may include an anisotropic etching process (or directional etching process), such as a reactive ion etching (RIE) process, plasma etching, inductively coupled plasma (ICP) etching, or a dry etching process with a combination thereof.

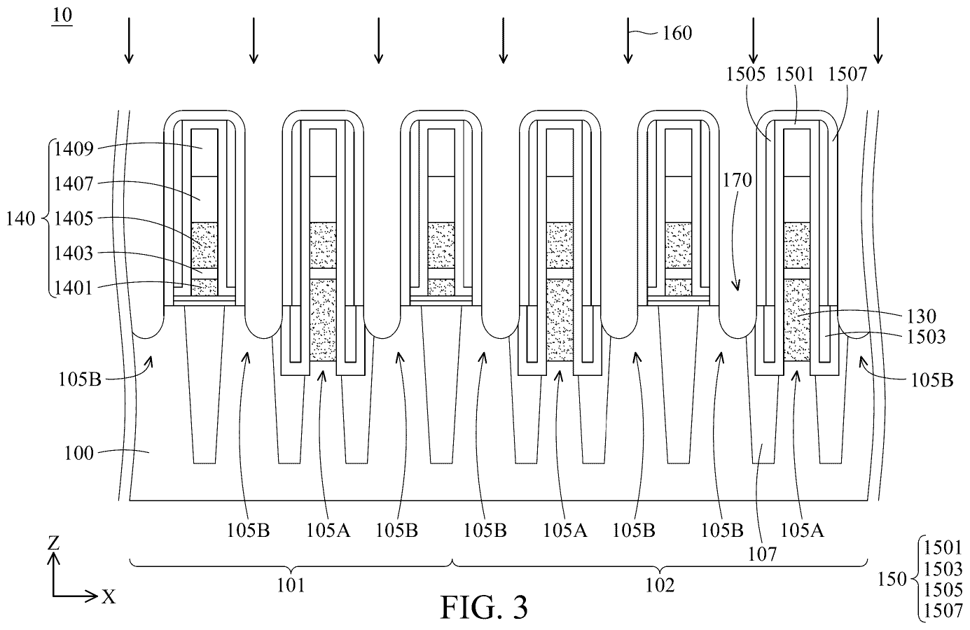

Next, referring to FIG. 3, an etching process 160 is performed on the substrate 100 to form a trench 170 and expose the second active region 105B. In an embodiment, the etching process 160 may include an anisotropic etching process (or directional etching process), such as reactive ion etching, plasma etching, inductively coupled plasma (ICP) etching, or a dry etching process with a combination thereof.

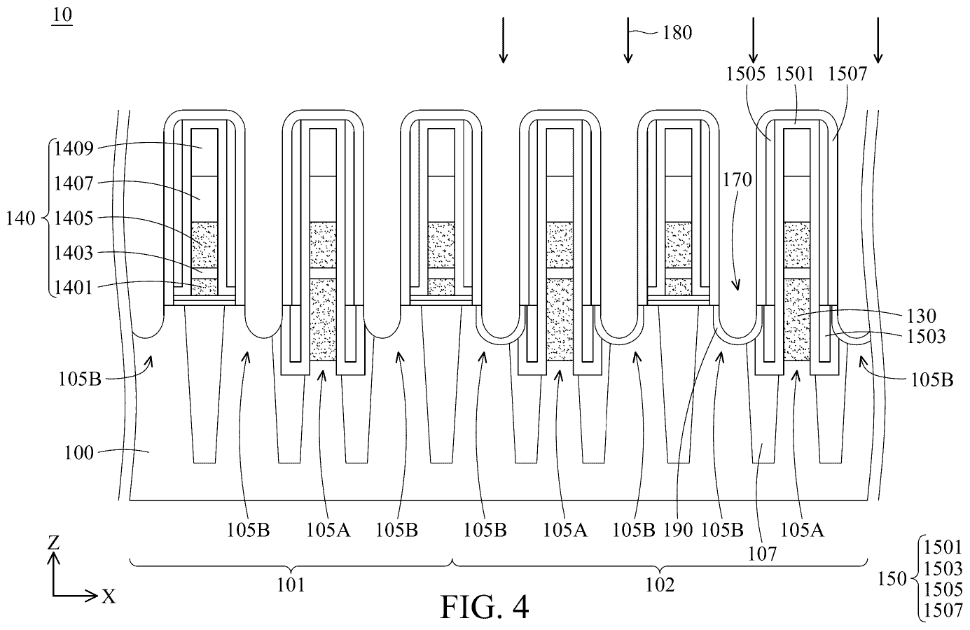

Next, referring to FIG. 4, an ion implantation process 180 is performed in the trench 170 located in the boundary region 102 of the array region of the substrate 100, to form an insulating layer 190 at the bottom of the trench 170 and covering the second active region 105B. More specifically, in an embodiment, the ion implantation process 180 includes forming a patterned mask (not shown) to cover the central region 101 and the peripheral region 103 of the substrate 100 (see FIG. 1), while exposing the boundary region 102, performing the ion implantation process 180, and subsequently removing the patterned mask. In an embodiment, the element used in the ion implantation process 180 includes xenon (Xe), krypton (Kr), iron (Fe), argon (Ar), or nitrogen (N). According to the embodiments of the present disclosure, by performing the additional ion implantation process 180 and implanting selected elemental ions into the second active region 105B located in the boundary region 102, an insulating layer 190 having insulating properties may be formed at the surface of the second active region 105B in the boundary region 102.

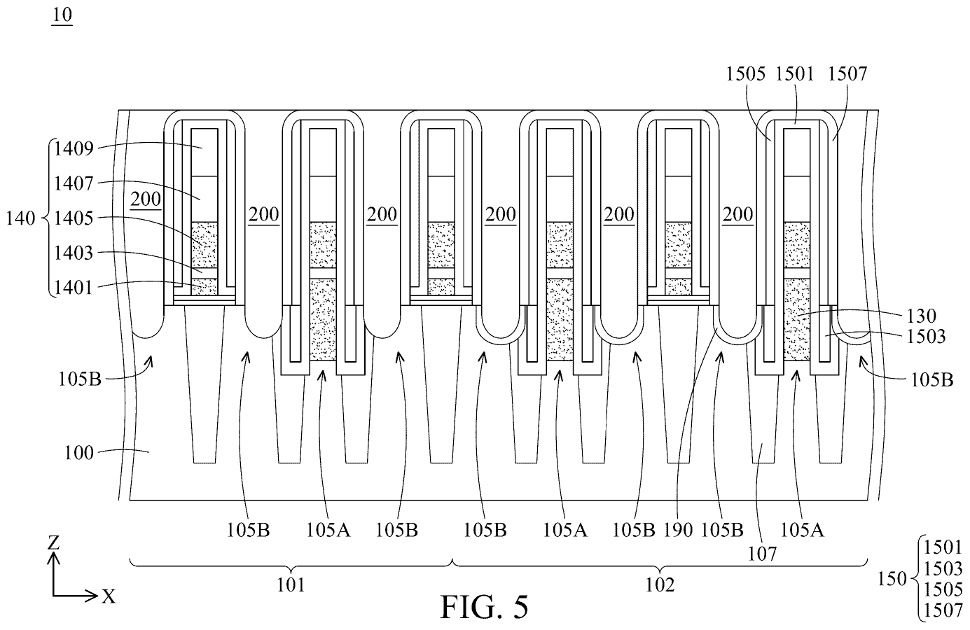

Next, referring to FIG. 5, a capacitor contact structure 200 is formed on the active region 105B. As shown in FIG. 5, the second active region 105B located in the boundary region 102 is electrically isolated from the capacitor contact structure 200 by the insulating layer 190. In an embodiment, the capacitor contact structure 200 may include, from bottom to top, a conductive layer, a silicide layer, and another conductive layer. In an embodiment, a level of an upper surface of the second active region 105B is higher than a level of a top surface of the first active region 105A. In an embodiment, the conductive layers may include doped polysilicon, metal, or metal nitride. In one embodiment, the silicide layer may include a metal silicide, such as tungsten silicide (WSi) or cobalt silicide (CoSi).

In summary, the embodiments of the present disclosure utilize an additional ion implantation process to implant selected elemental ions into the second active region located in the boundary region, thereby forming an insulating layer on the surface of the second active region in the boundary region. This ensures that the capacitor contact structure formed thereon is electrically isolated from the second active region. Therefore, even if misalignment occurs in subsequent processes and a leakage path is created by the capacitor contact structure in the boundary region, the insulating layer formed on the surface of the second active region in the boundary region may prevent the generation of leakage current, thereby maintaining the electrical performance of the memory device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a memory device, comprising:
providing a substrate, wherein an array region of the substrate comprises a central region and a boundary region surrounding the central region, and wherein the substrate comprises a first active region and a second active region separated by an isolation structure;
sequentially forming a bit line contact and a bit line structure over the first active region of the substrate;
conformally forming a dielectric liner on the substrate to cover sidewalls of the bit line contact and the bit line structure and a top surface of the bit line structure;
performing an etching process on the substrate to form a trench and expose the second active region;
performing an ion implantation process in the trench located in the boundary region of the substrate to form an insulating layer at a bottom of the trench and covering the second active region; and
forming a capacitor contact structure over the second active region.

2. The method as claimed in claim 1, wherein an element used in the ion implantation process is selected from xenon (Xe), krypton (Kr), iron (Fe), argon (Ar), or nitrogen (N).

3. The method as claimed in claim 1, wherein the second active region located in the boundary region is electrically isolated from the capacitor contact structure by the insulating layer.

4. The method as claimed in claim 1, wherein the insulating layer is formed at the bottom of the trench and is embedded in the substrate.

5. The method as claimed in claim 1, wherein a level of a lowest surface of the insulating layer is positioned above a level of a top surface of the first active region.

6. The method as claimed in claim 1, wherein performing the ion implantation process further comprises:
forming a patterned mask to cover the central region of the array region of the substrate and expose the boundary region of the array region of the substrate;
performing the ion implantation process; and
removing the patterned mask.

7. The method as claimed in claim 1, wherein the capacitor contact structure comprises, from bottom to top, a first conductive layer, a silicide layer, and a second conductive layer.

8. The method as claimed in claim 7, wherein the silicide layer comprises tungsten silicide (WSi) or cobalt silicide (CoSi).

9. The method as claimed in claim 1, wherein the bit line structure comprises a multi-layer stack including a plurality of conductive layers and at least one dielectric layer and a cap layer.

10. The method as claimed in claim 9, wherein the plurality of conductive layers comprise tungsten (W), titanium (Ti), titanium nitride (TiN), or a combination thereof.

11. The method as claimed in claim 1, wherein forming the dielectric liner comprises depositing a plurality of dielectric layers, and wherein the plurality of dielectric layers comprise at least a nitride material and an oxide material.

12. The method as claimed in claim 1, wherein the dielectric liner comprises a conformally deposited first spacer material layer and at least one subsequently deposited filling spacer material layer.

13. The method as claimed in claim 1, wherein the etching process is an anisotropic etching process selected from reactive ion etching, plasma etching, inductively coupled plasma etching, or a combination thereof.

14. The method as claimed in claim 1, wherein the dielectric liner electrically isolates the capacitor contact structure formed over the second active region from the bit line contact disposed over the first active region.

15. A memory device, comprising:
a substrate, wherein an array region of the substrate comprises a central region and a boundary region surrounding the central region, and wherein the substrate comprises a first active region and a second active region separated by an isolation structure;
a bit line structure disposed over the first active region of the substrate;
a trench disposed over the second active region of the substrate;
an insulating layer located at a bottom of the trench and covering the second active region; and
a capacitor contact structure disposed over the second active region and filled into the trench.

16. The memory device as claimed in claim 15, wherein the insulating layer comprises ions implanted from an element selected from xenon (Xe), krypton (Kr), iron (Fe), argon (Ar), and nitrogen (N).

17. The memory device as claimed in claim 15, wherein the second active region located in the boundary region is electrically isolated from the capacitor contact structure by the insulating layer.

18. The memory device as claimed in claim 15, wherein a level of a lowest surface of the insulating layer is higher than a level of a top surface of the first active region.

19. The memory device as claimed in claim 15, wherein the insulating layer is formed at the bottom of the trench and is at least partially embedded within the substrate.

20. The memory device as claimed in claim 15, wherein the capacitor contact structure is spaced apart from the bit line structure by the dielectric liner.
